(19) United States
(12) Patent Application Publication
(10) Pub. No.: US 2018/0202287 A1
(43) Pub. Date: Jul. 19, 2018

(54) SINUSOIDAL EXCITATION METHOD AND APPARATUS FOR MULTI-POLE ACOUSTIC LOGGING WHILE DRILLING

(71) Applicant: Institute of Geology and Geophysics, Chinese Academy of Sciences, Beijing (CN)

(72) Inventors: Yuntao SUN, Beijing (CN); Wenxuan CHEN, Beijing (CN); Wenxiu ZHANG, Beijing (CN); Yongyou YANG, Beijing (CN); Qingyun DI, Beijing (CN); Jian ZHENG, Beijing (CN)

(21) Appl. No.: 15/708,984

(22) Filed: Sep. 19, 2017

(30) Foreign Application Priority Data
Jan. 19, 2017 (CN) 201710044225.0

(51) Int. Cl. E21B 47/14; G01V 1/00; G01V 1/46; G01V 1/48; G01V 1/52; H03F 3/42; H03F 3/26; H03F 3/213

(52) U.S. Cl. CPC E21B 47/14; G01V 1/005; G01V 1/46; G01V 1/48; G01V 1/52; H03F 2203/7206; H03F 3/26; H03F 3/213; G01V 2200/16; G01V 2210/127; G01V 2210/6161; H03F 3/423

(57) ABSTRACT

In an apparatus for multi-pole acoustic logging while drilling, a N-cycle sinusoidal wave signal is generated by utilizing a signal processor, and amplified into a high-voltage sinusoidal excitation signal by utilizing a power amplifier, and output to a transmitting transducer. The signal processor simultaneously generates an enable signal. The enable signal includes a transient discharge enable signal. The power amplifier is connected with a transient discharge circuit. After the signal processor generates N cycles of a sinusoidal wave, the transient discharge enable signal enables the transient discharge circuit to discharge to release an energy storage current of a power transformer so as to eliminate a high-voltage ringing effect and improve an excitation efficiency of the transducer.

### TECHNICAL FIELD

The present invention belongs to the field of signal excitation, and particularly relates to a sinusoidal excitation method and apparatus for multi-pole acoustic logging while drilling.

### BACKGROUND

The logging while drilling (LWD) technology has been developing rapidly since the 1980s. Compared with conventional wireline logging, logging while drilling may provide important information in an oil exploration and development process immediately and accurately, and provide a reliable technical support for improving the operating efficiency. The logging while drilling is involved in acoustics, telecommunications jurisprudence, nuclear magnetism, radioactivity and other disciplines. In recent years, related logging while drilling instruments have been developed. The logging while drilling instruments have experienced the development of monopoles and dipoles, and have developed towards multi-pole currently. A compression velocity and a shear velocity of a stratum, a porosity of the stratum, a permeability and a borehole wall stability can be measured by multi-pole acoustic while drilling.

Compared with a conventional wireline acoustic logging instrument, it is largely influenced by drilling noises, drilling fluid circulation noises and a drill collar wave in an acoustic logging while drilling process; and a broadband and high-power and high-efficiency excitation manner is crucial to obtain high-quality acoustic logging data. A traditional acoustic excitation manner commonly adopts a rectangular pulse excitation manner, and a width of a pulse is related to a resonant frequency of a transmitting transducer. In general, its width is one-half of the resonant frequency. However, under such an operating manner, selecting its basic frequency is limited, which requires impedance matching of a power transformer and the transmitting transducer, and strictly operates on the resonant basic frequency of the transmitting transducer. For different frequency operating points of multipole, if such a method is employed, it is necessary to select a plurality of power transformers and transmitting transducers (to achieve resonance at different frequency points). This will greatly increase the design complexity and research and development costs of the instrument.

At this stage, for the multi-pole acoustic while drilling instrument, a sinusoidal wave pulse excitation source is commonly employed.

Because a rectangular pulse occupies a relatively wide frequency band in a frequency domain, it is relatively low in system power consumption and excitation efficiency in comparison with a sinusoidal pulse excitation manner. An acoustic while drilling transmitting transducer excitation manner adopting a sinusoidal pulse is more efficient than a rectangular pulse excitation manner. An excitation emission transducer with peak efficiency may be realized by adopting a sinusoidal wave excitation manner by changing a frequency of a sinusoidal wave without changing resonance frequency points of the power amplifier and the transmitting transducer.

At this stage, three cycles of a sinusoidal wave is commonly used as an excitation pulse of the transmitting transducer. For the multi-pole acoustic logging while drilling instrument, three cycles of the sinusoidal wave requires at least two frequency points to excite the transmitting transducer to operate (monopoles, dipoles, polarizers and quadrupoles do not operate at a frequency point). In the actual operation, the acoustic logging while drilling adopting the sinusoidal wave excitation manner has the following two problems:

1. a high-voltage source generated by excitation always operates, and an energy storage capacitor behind it is always in a charged state, resulting in wasted power consumption; and

2. in a case where the power transformer and the transmitting transducer do not operate at a resonant frequency point (in general, multi-pole acoustic excitation can at least operate at two frequency points), or are not matched well, in a three-cycle sinusoidal wave excitation process, a magnet inside the power transformer will have an energy storage effect, once the three-cycle sinusoidal wave excitation is over, the power transformer will release energy, and a shock trailing smear, that is, a so-called high-voltage ringing effect, is added behind a three-cycle sinusoidal wave excitation signal, which has a great impact on an excitation effect of the transmitting transducer.

These two problems will increase the system power consumption, and reduce the excitation efficiency of the transducer.

### SUMMARY

In view of the above-mentioned problems, the present invention provides a sinusoidal wave excitation method and apparatus for multi-pole acoustic logging while drilling. On the basis of sinusoidal wave pulse excitation, a discharging manner of adopting a controllable high-voltage power supply and a transient power transformer is disclosed, which improves the transmitting efficiency while reducing the system power consumption.

In one of the embodiments in the current disclosure, a sinusoidal excitation method for multi-pole acoustic logging while drilling includes the following steps: generating a N-cycle sinusoidal wave signal by utilizing a signal processor; amplifying the sinusoidal wave signal into a high-voltage sinusoidal excitation signal by utilizing a power amplifier, and outputting it to a transmitting transducer; and generating an enable signal by the signal processor, wherein the enable signal includes a transient discharge enable signal.

The power amplifier is connected with a transient discharge circuit. After the signal processor generates N cycles of a sinusoidal wave, the transient discharge enable signal enables the transient discharge circuit to discharge and release an energy storage current of a power transformer, so as to eliminate a high-pressure ringing effect and improve an excitation efficiency of the transducer.

Further, the transient discharge circuit includes a gate drive chip and two power MOS transistors. The two MOS transistors are connected in parallel. Gates of the MOS transistors connected in parallel are further connected with the gate drive chip. Sources of the MOS transistors connected in parallel are connected with a resistor. And drains of the MOS transistors connected in parallel are connected with two primary ports of the power amplifier, respectively. The other end of the resistor is grounded; and

After the signal processor generates N cycles of the sinusoidal wave, the enable signal controls the gates of the two MOS transistors to enable the MOS transistors to be immediately conducted after passing through the gate drive chip, and an energy storage current of the power transformer is rapidly discharged by means of the resistor.

Further, the power transformer is connected with a high-voltage generating circuit, and the high-voltage generating circuit provides a high-voltage drive to the power amplifier. The high-voltage generating circuit includes a high-voltage power supply module and a high-voltage energy storage capacitor, and the high-voltage power supply module converts a low voltage into a high voltage to be output to the high-voltage energy storage capacitor for charging the high-voltage energy storage capacitor, and the high-voltage energy storage capacitor is connected with the power amplifier to provide the high-voltage drive to the power amplifier. The enable signal further includes a high-voltage power supply enable signal

The high-voltage power supply module includes an enable control terminal, and the enable control terminal is connected with the signal processor. The high-voltage power supply enable signal controls the enable control terminal, and after the signal processor generates N cycles of the sinusoidal wave, an output of the high-voltage power supply module is rapidly cut off.

Further, the power amplifier includes a Class B push-pull amplifier circuit and a power transformer, wherein the power transformer has a center tap, a primary port and a secondary port, the primary port has a center tap, and an inductance of the power transformer is matched with an impedance of the transmitting transducer.

Further, a valid time of the transient discharge enable signal is adjusted according to a magnetic core material of the power transformer, a turns ratio, and a peak voltage of the transducer.

Further, a resistance of the resistor R8 is less than 1 ohm.

Further, the signal processor is a signal processor with an analog signal output function or a combination of a digital signal processor and a digital-to-analog converter.

In another embodiment of the current disclosure, a sinusoidal excitation apparatus for multi-pole acoustic logging while drilling adopts the above excitation method and includes a signal processing module, a high-voltage generating module, a power amplification module and a transient discharge module. The high-voltage generating module includes a high-voltage generating circuit and a high-voltage generating circuit closing module. The transient discharge module includes a transient discharge circuit and a transient discharge circuit conducting module. The signal processing module generates a sinusoidal signal and an enable signal. The enable signal controls the turning on of the high-voltage generating circuit closing module and the transient discharge circuit conducting module.

The present invention has advantageous effects:

(1) the excitation method of the present invention adopts a manner of externally connecting the discharge circuit to quickly release the energy storage current of the power transformer so as to eliminate the high-voltage ringing effect of the power transformer; and

(2) the present invention adopts a manner of the controllable high-voltage power supply to reduce the system power consumption in a non-operating state.

### BRIEF DESCRIPTION OF THE DRAWINGS

FIG. 1 is a schematic diagram of a sinusoidal excitation structure for multi-pole acoustic logging while drilling;

FIG. 2 is a schematic diagram of a sinusoidal excitation circuit for multi-pole acoustic logging while drilling;

FIG. 3 is a schematic diagram of a sinusoidal excitation signal when a valid time of a SW enable signal of a transient discharge circuit is 100 us and signals loaded on a point X1p and a point X1n of a transducer according to an embodiment;

FIG. 4 is a schematic diagram of a sinusoidal excitation signal when a valid time of a SW enable signal of a transient discharge circuit is 200 us and signals loaded on a point X1p and a point X1n of a transducer according to an embodiment; and

FIG. 5 is a schematic diagram of a sinusoidal excitation signal when a valid time of a SW enable signal of a transient discharge circuit is 400 us and signals loaded on a point X1p and a point X1n of a transducer according to an embodiment.

### DETAILED DESCRIPTION

Objectives, technical solutions and advantages of the present invention will become more apparent from the following detailed description of the present invention when taken in conjunction with accompanying drawings. It should be understood that specific embodiments described herein are merely illustrative of the present invention and are not intended to limit the present invention.

Rather, the present invention encompasses any alternatives, modifications, equivalents, and solutions made within the spirit and scope of the present invention as defined by the claims. Further, in order to give the public a better understanding of the present invention, some specific details are described below in detail in the following detailed description of the present invention. It will be appreciated by those skilled in the art that the present invention may be understood without reference to the details.

### Example 1

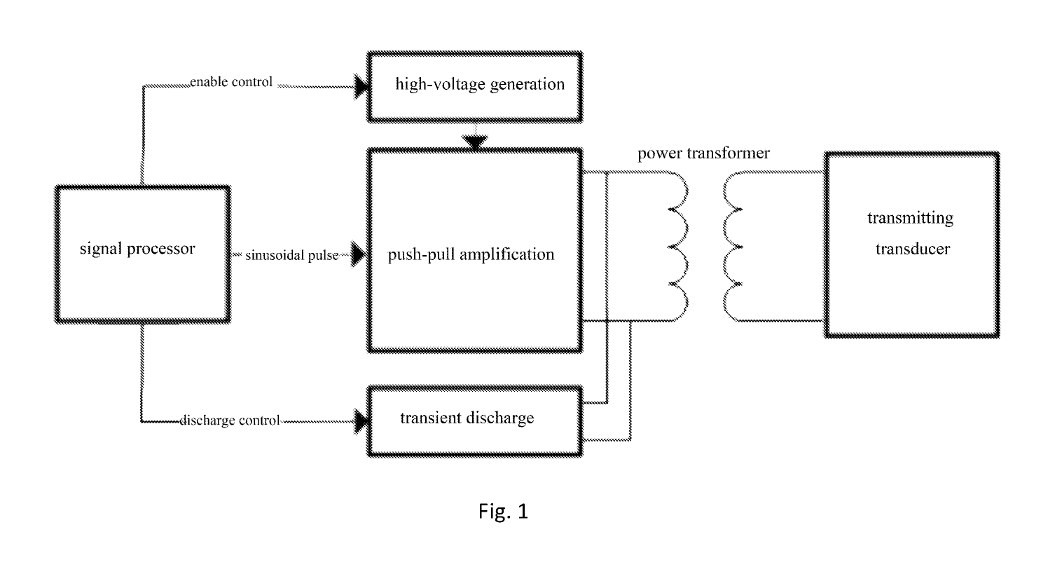

Provided is a sinusoidal excitation method for multi-pole acoustic logging while drilling. A sinusoidal excitation structure for multi-pole acoustic logging while drilling is shown in FIG. 1. A three-cycle sinusoidal wave signal SIN with an amplitude of a 3.3 v peak-to-peak value is generated by using a DSP signal processor. A low-voltage sinusoidal wave (3.3 V peak value) output by the signal processor DSP is amplified into a 400V sinusoidal wave excitation signal by adopting a class B push-pull amplifier circuit. A sinusoidal wave excitation signal, output from the push-pull amplifier circuit, with a 400 V peak value is amplified into a sinusoidal wave excitation signal with a 2000 V peak value by utilizing a power transformer with a turns ratio of 1:5. A 400 V direct-current high-voltage power supply is generated from a low voltage 10 V to 15 V by a high-voltage generating circuit, with an output power which is controlled to be within a 10 W, and provides a high voltage to the power transformer. An inductance of the power transformer is set according to an equivalent circuit of an acoustic transmitting transducer to achieve impedance matching of a transmitting circuit. A signal is output to the transmitting transducer.

The power transformer has a center tap, two input ports and one output port.

The high-voltage generating circuit includes a high-voltage power supply module and a high-voltage energy storage capacitor C1. The high-voltage power supply module converts the low voltage into a high voltage to be output to the high-voltage energy storage capacitor C1 to charge the high-voltage energy storage capacitor C1. The high-voltage energy storage capacitor C1 is connected with the power amplifier to provide a high-voltage drive to the power amplifier.

The signal processor DSP generates a transient discharge enable signal SW and a power amplifier is connected with a transient discharge circuit. After the signal processor generates three cycles of a sinusoidal wave, the transient discharge enable signal SW enables the transient discharge circuit to discharge to release an energy storage current of the power amplifier, so as to eliminate a high-pressure ringing effect and improve an excitation efficiency of the transducer.

The transient discharge circuit includes a gate drive chip U3 and two diodes Q3 and Q4. The two diodes are connected in parallel. The gates of the diodes connected in parallel are connected with the gate drive chip U3. The sources of the diodes connected in parallel are connected with a resistor R8. The drains of the diodes connected in parallel are respectively connected with two output ends of the power amplifier. The other end of the resistor R8 is grounded. After the signal processor generates N cycles of a sinusoidal wave with a frequency f, an enable signal controls the gates of the two diodes Q3 and Q4 to immediately conduct the diodes after passing through the gate drive chip U3. The energy storage current of the power amplifier is rapidly discharged by means of the resistor R8. A resistance of the resistor R8 is below 1 ohm. The smaller the resistance of the resistor R8 is, the rapider a discharge speed is.

Moreover, the signal processor DSP generates a high-voltage power supply enable signal CNRL. The high-voltage power supply module includes an enable control terminal EN. The enable control terminal EN is connected with the signal processor.

The high-voltage power supply enable signal CNRL controls the enable control terminal EN. After the signal processor generates three cycles of the sinusoidal wave, an output of the high-voltage power supply module is rapidly cut off. The high-voltage power supply module U1 converts a direct-current power supply with a low voltage 15 V into a direct-current power supply +HV with a high voltage 400 V under the enabling of the control signal CTRL. The direct-current power supply +HV with a high voltage 400 V charges the high-voltage energy storage capacitor C1 through a current-limiting resistor R1 (an output power is controlled at 10 W). D1 is a current-limiting diode, which prevents the current from being too large to damage the high-voltage power supply module and the discharge circuit behind it.

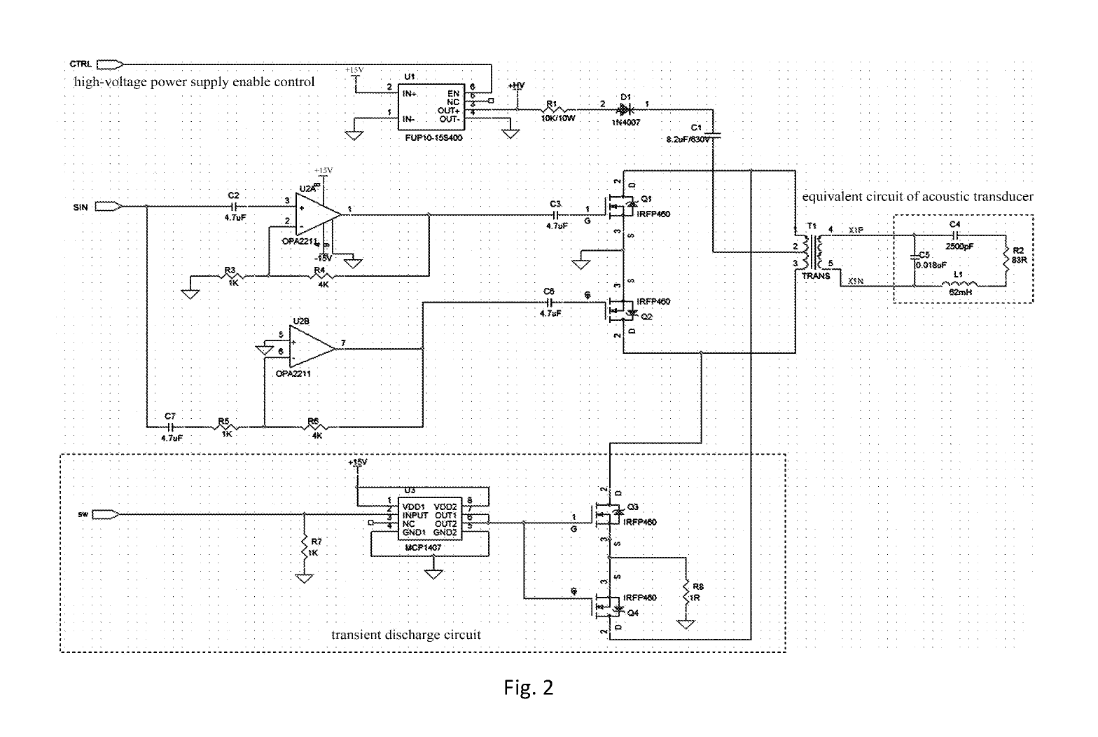

A schematic diagram of a sinusoidal excitation circuit for multi-pole acoustic logging while drilling is as shown in FIG. 2.

A sinusoidal excitation apparatus for multi-pole acoustic logging while drilling adopts the above excitation method.

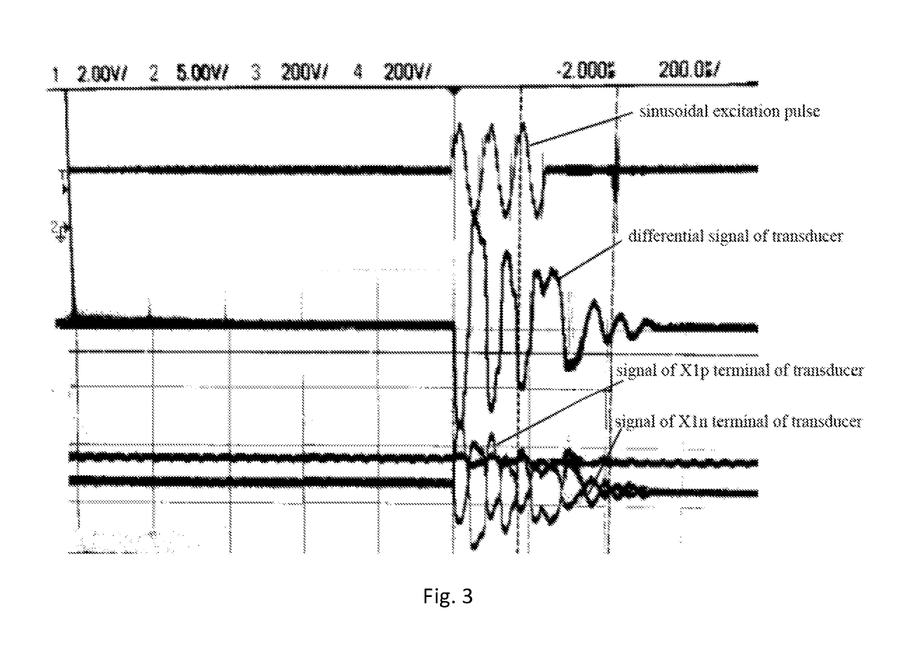

A relationship between sinusoidal excitation signals when valid times of enable signals SW of a transient discharge circuit are 100 μs, 200 μs and 400 μs and signals loaded on a point X1p and a point X1n of a transducer is as shown in FIG. 3 to FIG. 5.

It can be seen from FIG. 3, after excitation of three cycles of a sinusoidal pulse when the valid time is 100 μs, a ringing amplitude is reduced but not obvious, and a ringing trailing smear is longer. It is indicated that a function of the transient discharge circuit is not obvious under this state. The high-voltage ringing effect of the power transformer is eliminated well.

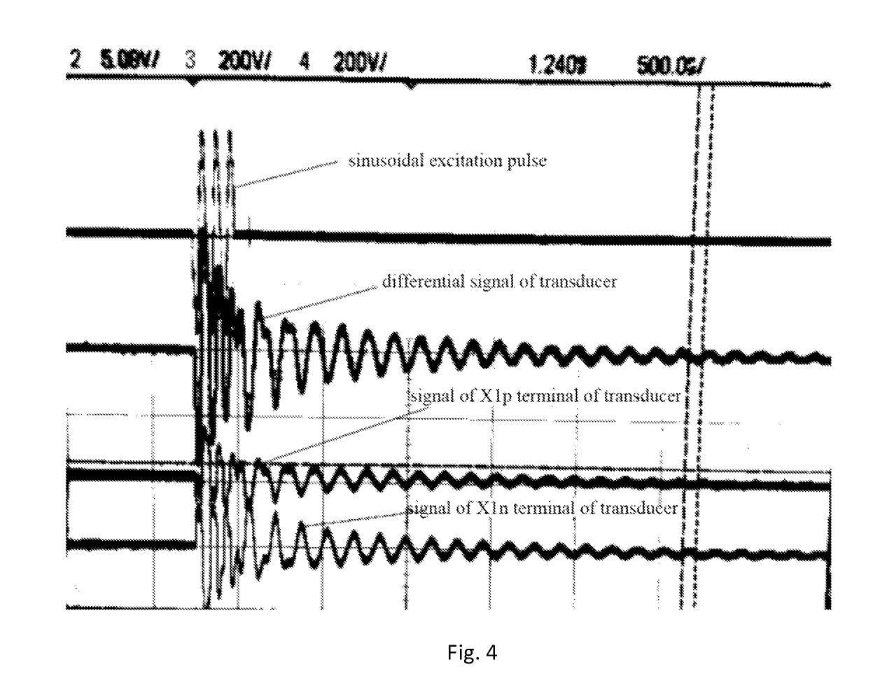

It can be seen from FIG. 4, when the valid time of the enable signal SW of the transient discharge circuit is 200 μs, it may be seen that after excitation of three cycles of the sinusoidal pulse, there are some trailing smears. However, the function of the transient discharge circuit is obvious, and most of the energy storage current of the power transformer is released, so that its ringing effect is reduced.

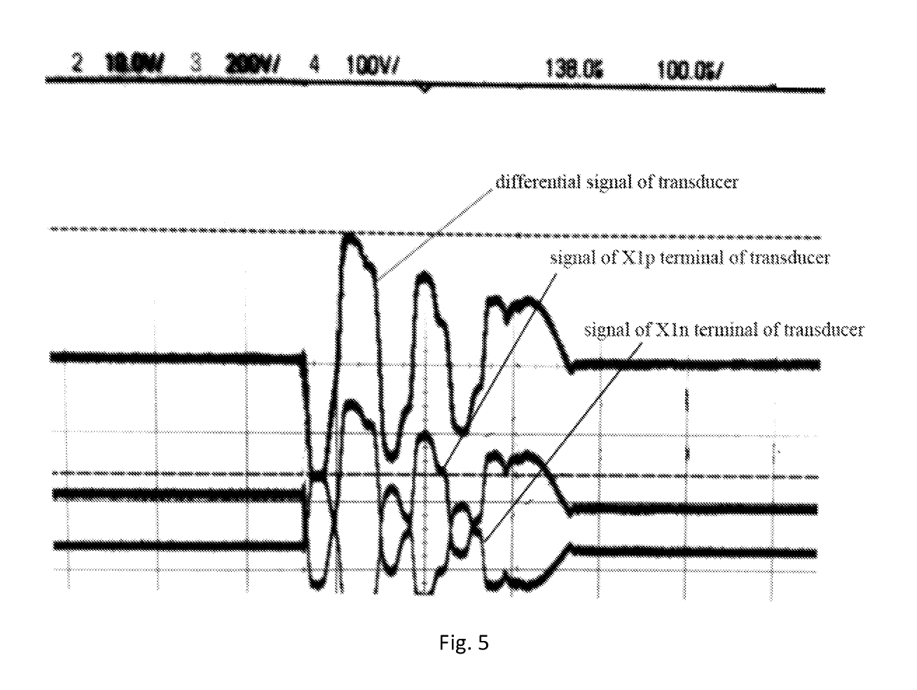

It can be seen from FIG. 5, when the valid time of the enable signal SW of the transient discharge circuit is 400 μs, it may be seen that after excitation of three cycles of the sinusoidal pulse, there are no trailing smears. However, it is indicated that the function of the transient discharge circuit is obvious, and the energy storage current of the power transformer is basically released, so that its ringing effect is reduced.

In a further embodiment, a sinusoidal excitation apparatus for multi-pole acoustic logging while drilling adopts the above excitation method. The apparatus includes a signal processing module, a high-voltage generating module, a power amplification module and a transient discharge module. The high-voltage generating module includes a high-voltage generating circuit and a high-voltage generating circuit closing module, and the transient discharge module includes a transient discharge circuit and a transient discharge circuit conducting module. The signal processing module generates a sinusoidal signal and an enable signal, and the enable signal controls the turning on of the high-voltage generating circuit closing module and the transient discharge circuit conducting module

1. A sinusoidal excitation method for multi-pole acoustic logging while drilling, comprising:
generating a N-cycle sinusoidal wave signal and an enable signal in a signal processor, wherein the enable signal comprises a transient discharge enable signal and N is a positive integer;
amplifying the sinusoidal wave signal into a high-voltage sinusoidal excitation signal in a power amplifier; and
outputting the high-voltage sinusoidal excitation signal to a transmitting transducer;
transmitting a transient discharge enable signal to a transient discharge circuit coupled with a power transformer; and
discharging an energy stored in the power transformer through the discharge circuit so as to eliminate a high pressure ringing effect and improve an excitation efficiency of the transmitting transducer.

2. The sinusoidal excitation method for multi-pole acoustic logging while drilling according to claim 1, wherein the transient discharge circuit comprises a gate drive chip and two high-power MOS transistors, wherein the two MOS transistors are connected in parallel, gates of the two parallelly connected MOS transistors are connected with the gate drive chip, sources of the two parallelly connected MOS transistors are connected with a first end of a resistor, and drains of the two parallelly connected MOS transistors are connected with two primary ports of the power amplifier, respectively, a second end of the resistor is grounded, and
wherein, in the discharging step, the transient enable signal passes through the gate drive chip and controls the gates of the two parallelly connected MOS transistors to turn on the MOS transistors so that the energy stored in the power transformer is discharged via the resistor.

3. The sinusoidal excitation method for multi-pole acoustic logging while drilling according to claim 2, wherein the power transformer is connected with a high-voltage generating circuit, and the high-voltage generating circuit provides a high-voltage to drive the power amplifier; the high-voltage generating circuit comprises a high-voltage power supply module and a high-voltage energy storage capacitor, and the high-voltage power supply module converts a low voltage into a high voltage to be output to the high-voltage energy storage capacitor for charging the high-voltage energy storage capacitor, and the high-voltage energy storage capacitor is connected with the power amplifier to provide the high-voltage drive to the power amplifier;
the enable signal further comprises a high-voltage power supply enable signal;
the high-voltage power supply module comprises an enable control terminal, and the enable control terminal is connected with the signal processor; and
the high-voltage power supply enable signal controls the enable control terminal, and after the signal processor generates the N cycles of the sinusoidal wave, an output of the high-voltage power supply module is turned off.

4. The sinusoidal excitation method for multi-pole acoustic logging while drilling according to claim 2, wherein the power amplifier comprises a Class B push-pull amplifier circuit and a power transformer, wherein the power transformer has a center tap, a primary port and a secondary port, the primary port has a center tap, and an inductance of the power transformer matches an impedance of the transmitting transducer.

5. The sinusoidal excitation method for multi-pole acoustic logging while drilling according to claim 4, further comprising adjusting a duration of the transient discharge enable signal according to a magnetic core material of the power transformer, a turns ratio, and a peak voltage of the transducer.

6. The sinusoidal excitation method for multi-pole acoustic logging while drilling according to claim 2, wherein a resistance of the resistor is less than 1 ohm.

7. The sinusoidal excitation method for multi-pole acoustic logging while drilling according to claim 2, wherein the signal processor has an analog signal output function or a combination of a digital signal processor and a digital-to-analog converter.

8. A sinusoidal excitation apparatus for multi-pole acoustic logging while drilling, comprising:
a signal processor, a high-voltage generating module, a power amplifier, a power transformer, and a transient discharge module;
wherein the signal processor is connected with and sends signals to the high-voltage generating module, the power amplifier, and the transient discharge module, respectively,
wherein the power amplifier and the transient discharge module are coupled with the power transformer,
wherein the high-voltage generating module comprises a high-voltage generating circuit and a high-voltage generating circuit closing module, and the transient discharge module comprises a transient discharge circuit and a transient discharge circuit conducting module; and
the signal processor generates a sinusoidal signal and an enable signal, and the enable signal controls the high-voltage generating circuit closing module and the transient discharge circuit conducting module.

9. The sinusoidal excitation apparatus according to claim 8, wherein the transient discharge circuit comprises a gate drive chip and two high-power MOS transistors, wherein the two MOS transistors are connected in parallel, gates of the two parallelly connected MOS transistors are connected with the gate drive chip, sources of the two parallelly connected MOS transistors are connected with a first end of a resistor, and drains of the two parallelly connected MOS transistors are connected with two primary ports of the power amplifier, respectively, a second end of the resistor is grounded.
